(19) United States
(12) Patent Application Publication
(10) Pub. No.: US 2012/0038008 A1
(43) Pub. Date: Feb. 16, 2012

(54) Field Effect Transistor Device with Self-Aligned Junction and Spacer

(75) Inventors: Dechao Guo, Wappingers Falls, NY (US); Pranita Kulkarni, Slingerlands, NY (US); Ramachandran Muralidhar, Mahopac, NY (US); Chun-Chen Yeh, Clifton Park, NY (US)

(73) Assignee: INTERNATIONAL BUSINESS MACHINES CORPORATION, Armonk, NY (US)

(21) Appl. No.: 12/857,017

(22) Filed: Aug. 16, 2010

(51) Int. Cl. H01L 29/78; H01L 21/336

(52) U.S. Cl. 257/408; 438/305; 257/E21.437; 257/E29.266

(57) ABSTRACT

In one aspect of the present invention, a method for fabricating a field effect transistor device includes forming a dummy gate stack on a first portion of a substrate, forming a source region and a drain region adjacent to the dummy gate stack, forming a ion doped source extension portion in the substrate, forming an ion doped drain extension portion in the substrate, forming a first spacer portion adjacent to the dummy gate stack, removing the dummy gate stack to expose a channel region of the substrate, a portion of the ion doped source extension portion, and a portion of the ion doped drain extension portion, forming a second spacer portion on the exposed portion of the ion doped source extension portion and on the exposed portion of the ion doped drain extension portion, and forming a gate stack on the exposed channel region of the substrate.

### FIELD OF INVENTION

The present invention relates to semiconductor field effect transistors.

### DESCRIPTION OF RELATED ART

Planar field effect transistor (FET) devices include a gate stack disposed on a channel region of a substrate and source and drain regions disposed adjacent to the channel region. The source and drain regions may be electrically connected to other devices via conductive contacts.

A number of planar FETs may be grouped on a substrate; the distance between the gates of the FETs or pitch, becomes smaller as the scale of the FETs are reduced. The reduction in pitch affects the gate length and electrostatic properties of the devices. The reduction in pitch results in source and drain contacts becoming closer, which may increase the parasitic capacitance of the FETs.

The source and drain regions include ion doped material adjacent to the channel region. The interfaces (junctions) between the source and drain regions and the channel region may be formed relative to the gate to affect the electrostatic properties of the device. An overlapped device includes a junction under the gate stack, while an underlapped device includes a junction disposed outside the edges of the gate stack. The amount of overlap in a device affects the parasitic capacitance in the device.

### BRIEF SUMMARY

In one aspect of the present invention, a method for fabricating a field effect transistor device includes forming a dummy gate stack on a first portion of a substrate, forming a source region and a drain region adjacent to the dummy gate stack, forming a ion doped source extension portion in the substrate, the source extension portion extending from the source region into the first portion of the substrate, forming an ion doped drain extension portion in the substrate, the drain extension portion extending from the drain region into the first portion of the substrate, forming a first spacer portion adjacent to the dummy gate stack, removing the dummy gate stack to expose a channel region of the substrate, a portion of the ion doped source extension portion, and a portion of the ion doped drain extension portion, forming a second spacer portion on the exposed portion of the ion doped source extension portion and on the exposed portion of the ion doped drain extension portion, and forming a gate stack on the exposed channel region of the substrate.

In another aspect of the present invention, a field effect transistor device includes a substrate including a source region, a drain region, and a channel region disposed between the source region and the drain region, wherein the source region is connected to the channel region with a source extension portion, and the drain region is connected to the channel region with a drain extension portion, a first spacer portion disposed on the source region, the drain region and a first portion of the source extension portion, and a first portion of the drain extension portion, a second spacer portion disposed on a second portion of the source extension portion, and a second portion of the drain extension portion, a gate stack portion disposed on the channel region.

Additional features and advantages are realized through the techniques of the present invention. Other embodiments and aspects of the invention are described in detail herein and are considered a part of the claimed invention. For a better understanding of the invention with the advantages and the features, refer to the description and to the drawings.

### BRIEF DESCRIPTION OF THE SEVERAL VIEWS OF THE DRAWINGS

The subject matter which is regarded as the invention is particularly pointed out and distinctly claimed in the claims at the conclusion of the specification. The forgoing and other features, and advantages of the invention are apparent from the following detailed description taken in conjunction with the accompanying drawings in which:

FIG. 1 illustrates a side cut-away view of an exemplary embodiment of a field effect transistor (FET) device.

FIGS. 2-6 illustrate side cut-away views of an exemplary method for fabricating the device of FIG. 1, where by:

FIG. 2 illustrates a substrate and a dummy gate stack;

FIG. 3 illustrates the removal of material from the dummy gate stack;

FIG. 4 illustrates the removal of an interfacial layer;

FIG. 5 illustrates the formation of a layer; and

FIG. 6 illustrates the formation of a gate stack.

### DETAILED DESCRIPTION

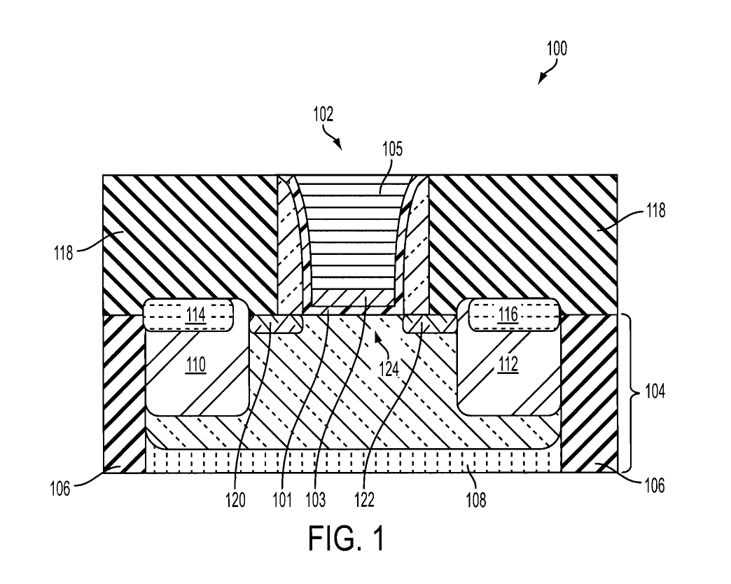

FIG. 1 illustrates a side cut-away view of an exemplary embodiment of a field effect transistor (FET) device 100. The device 100 includes a gate stack portion 102 disposed on channel region 124 of a substrate 104. The gate stack portion 102 may include, for example layer 101 disposed on the substrate 104, and a layer 103 disposed on the layer 101. The layer 101 may include a dielectric material, such as silicon dioxide or a high-k layer of material. The layer 103 may include a polysilicon material or a metallic gate material. A capping layer 105 including, for example, a polysilicon material may be disposed on the layer 103. The substrate 104 may include for example a silicon trench isolation (STI) portion 106 and a buried oxide portion 108.

The device 100 includes a source region 110 and a drain region 112. The source and drain regions 110 and 112 may be formed from epitaxially grown silicon material including, for example, SiC for nFET, SiGe for pFET. The source and drain regions 110 and 112 may include silicide regions 114 and 116 that include a silicide material such as, for example NiPtSi. A spacer material 118, such as, for example, silicon nitride or silicon oxide may be formed over the device 100.

The device 100 includes a source extension portion 120 and a drain extension portion 122. The source extension portion 120 extends from the source region 110 to the channel region 124 and the drain extension portion 122 extends from the drain region 112 to the channel region 124. The device 100 may be a p-type FET (PFET) or n-type FET (NFET) depending on the dopants used to fabricate the device 100. For a NFET device, the device 100 would include source and drain extension portions 120 and 122 that are primarily n-type doped, the channel region 124 includes primarily p-type dopants, The interface or junction between the source extension portion 120 and the drain extension portion 122 are aligned with the distal regions (edges) of the gate stack 102. A PFET device is similar to the NFET device described above however, the source and drain extension portions 120 and 122 are primarily p-type doped, and the channel region 124 includes n-type dopants. A spacer 126 is disposed over a portion of the source and drain extension portions 120 and 122. The spacer 126 may be formed from, for example a nitride or oxide material.

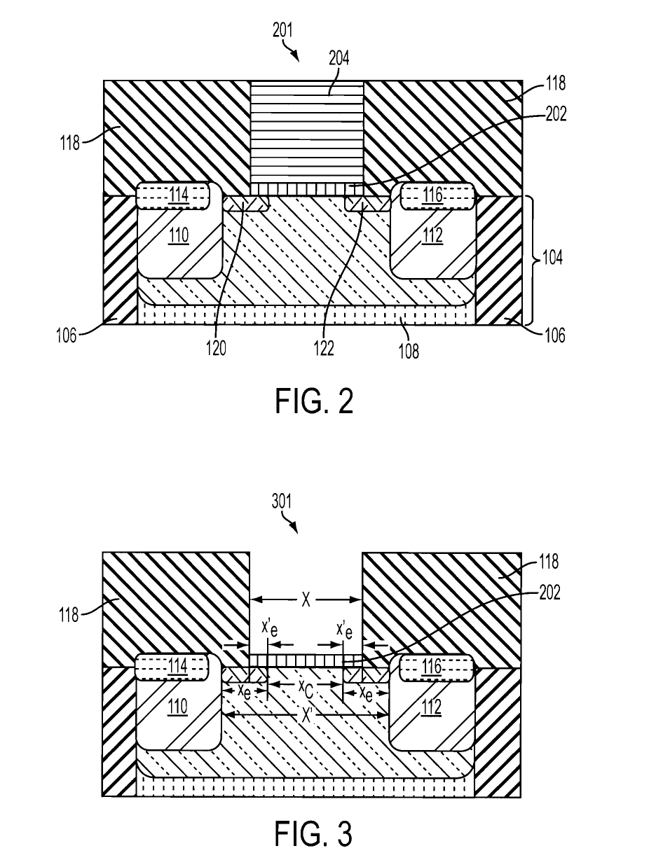

FIGS. 2-6 illustrate a side cut-away view of an exemplary method for fabricating the device 100 (of FIG. 1). Referring to FIG. 2, the illustrated embodiment includes a substrate 104 that includes a buried oxide portion 108 and a STI portion 106. A source region 110 and a drain region 112 include doped silicon material that may be formed from any suitable process such as, for example, epitaxially growing silicon that may be doped during the growth process, or during a subsequent doping process. A silicide material 114 and 116 may be formed on the source region 110 and the drain region 112 using a suitable silicidation process. A dummy gate stack 201 includes a interfacial layer 202 that may include, for example, an oxide or dielectric material disposed on the substrate 104 and a polysilicon material 204 disposed on the interfacial layer 202. A spacer material 118 that may include, for example, a nitride or oxide material is formed adjacent to the dummy gate stack 201 and over the source and drain regions 110 and 112. Doped source extension portion 120 and drain extension portion 122 extend from the source and drain regions 110 and 112 respectively to a region overlapped by the dummy gate 201.

FIG. 3 illustrates the resultant structure following the removal of the polysilicon material 204 (of FIG. 2) from the dummy gate stack 201. The removal of the polysilicon material 204 exposes the interfacial layer 202 and forms a cavity 301 defined by the spacer material 118 and the interfacial layer 202 having a width (x). The distance between the source and drain regions 110 and 112 has a length (x′). The source extension portion 120 and drain extension portion 122 each have lengths (xₑ) while the channel region between the source extension portion 120 and drain extension portion 122 has a length (x_{c}), such that x′=xₑ+xₑ+x_{c}, and x′>x. The interfacial layer 202 is disposed over portions of the source extension portion 120 and drain extension portion 122 having lengths (xₑ′), where xₑ′=(x-x_{c})/2.

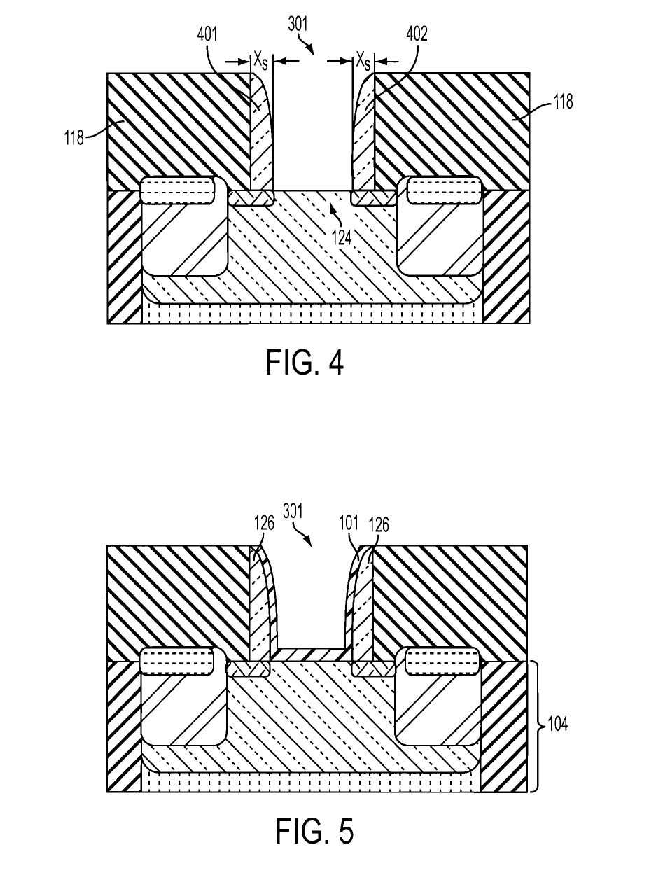

FIG. 4 illustrates the resultant structure following the removal of the interfacial layer 202 (of FIG. 2) by a suitable etching process such as, for example an anisotropic wet etching process that exposes the channel region 124 and portions of the source extension portion 120 and drain extension portion 122. Following the removal of the interfacial layer 202, a spacer 126 is formed in the cavity 301 over the exposed portions of the source extension portion 120 and drain extension portion 122 and adjacent to the spacer material 118. The spacer 126 may include, for example, an oxide or nitride material. The spacer 126 has a width of xₛ and may be formed by, for example, a deposition, masking and etching process.

FIG. 5 illustrates the resultant structure following the formation of a layer 101 in the cavity 301 on the channel region 124 of the substrate 104 and portions of the spacer 126. The layer 101 may include for example, dielectric material, such as silicon dioxide or a high-k layer of material.

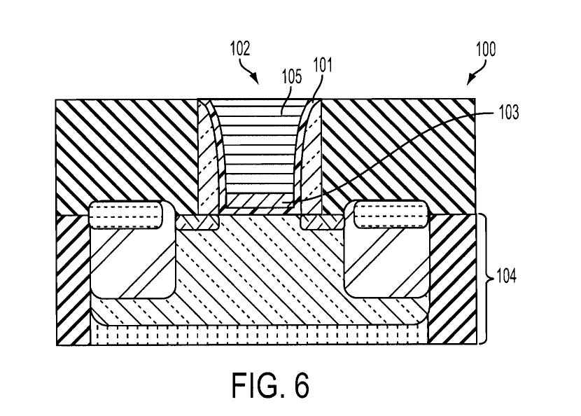

FIG. 6 illustrates the formation of the gate stack portion 102 on the channel region 124 to form the device 100. The gate stack portion 102 may include, for example layer 101 disposed on the substrate 104, and a layer 103 disposed on the layer 101. The layer 103 may include a polysilicon material or a metallic gate material. A capping layer 105, such as, for example a polysilicon material, may be disposed on the layer 103; filling the cavity 301 (of FIG. 5).

In the illustrated embodiment, the spacer 126 is formed over the exposed portions of the source extension portion 120 and drain extension portion 122. The width of the spacer 126 (xₛ) effects the overlapping and underlapping dimensions of the device 100. In the illustrated embodiment, the device is underlapped such that the distal portions of the source extension portion 120 and drain extension portion 122 are aligned outside of the distal edges of the gate stack 102 xₛ>xₑ′. In alternate embodiments, the width xₛ may be lesser such that the device is overlapped xₛ<xₑ′ (i.e., The gate stack 102 is partially disposed on distal portions of the source extension portion 120 and drain extension portion 122.).

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated

The diagrams depicted herein are just one example. There may be many variations to this diagram or the steps (or operations) described therein without departing from the spirit of the invention. For instance, the steps may be performed in a differing order or steps may be added, deleted or modified. All of these variations are considered a part of the claimed invention.

While the preferred embodiment to the invention had been described, it will be understood that those skilled in the art, both now and in the future, may make various improvements and enhancements which fall within the scope of the claims which follow. These claims should be construed to maintain the proper protection for the invention first described.

What is claimed is:

1. A method for fabricating a field effect transistor device, the method including:
forming a dummy gate stack on a first portion of a substrate;
forming a source region and a drain region adjacent to the dummy gate stack;
forming a ion doped source extension portion in the substrate, the source extension portion extending from the source region into the first portion of the substrate;
forming an ion doped drain extension portion in the substrate, the drain extension portion extending from the drain region into the first portion of the substrate;
forming a first spacer portion adjacent to the dummy gate stack;
removing the dummy gate stack to expose a channel region of the substrate, a portion of the ion doped source extension portion, and a portion of the ion doped drain extension portion;
forming a second spacer portion on the exposed portion of the ion doped source extension portion and on the exposed portion of the ion doped drain extension portion; and
forming a gate stack on the exposed channel region of the substrate.

2. The method of claim 1, wherein the dummy gate stack includes the interfacial layer disposed on the first portion of the substrate and a polysilicon layer disposed on the interfacial layer.

3. The method of claim 1, wherein the interfacial layer is removed using a wet etching process.

4. The method of claim 1, wherein forming the gate stack includes:
forming a layer of high-k material on the channel region of the substrate and portions of the second spacer portion; and
forming a layer of metallic material on the high-k layer.

5. The method of claim 1, wherein forming the gate stack includes:
forming a layer of dielectric material on the channel region of the substrate and portions of the second spacer portion; and
forming a layer of polysilicon material on the layer of dielectric material.

6. The method of claim 1, wherein the second spacer portion includes an oxide material.

7. The method of claim 1, wherein the second spacer portion includes a nitride material.

8. The method of claim 1, wherein the first spacer portion includes an oxide material.

9. The method of claim 1, wherein the first spacer portion includes a nitride material.

10. The method of claim 1, wherein a width of the second spacer portion (xₛ) is greater than a length of the exposed portion of the ion doped source extension portion (xₑ′).

11. A field effect transistor device including:
a substrate including a source region, a drain region, and a channel region disposed between the source region and the drain region, wherein the source region is connected to the channel region with a source extension portion, and the drain region is connected to the channel region with a drain extension portion;
a first spacer portion disposed on the source region, the drain region and a first portion of the source extension portion, and a first portion of the drain extension portion;
a second spacer portion disposed on a second portion of the source extension portion, and a second portion of the drain extension portion;
a gate stack portion disposed on the channel region.

12. The device of claim 11, wherein the gate stack portion includes a layer of high-k material disposed on the channel region and portions of the second spacer portion.

13. The device of claim 11, wherein the gate stack portion includes a layer of dielectric material disposed on the channel region and portions of the second spacer portion.

14. The device of claim 12, wherein the gate stack portion includes a metallic layer disposed on the high-k layer.

15. The device of claim 11, wherein the first spacer portion includes a nitride material.

16. The device of claim 11, wherein the first spacer portion includes an oxide material.

17. The device of claim 11, wherein the second spacer portion includes a nitride material.

18. The device of claim 11, wherein the second spacer portion includes an oxide material.

19. The device of claim 11, wherein the source region, the drain region, the source extension portion, and the drain extension portion are doped with ions.
